(19) United States
(12) Patent Application Publication
(10) Pub. No.: US 2008/0238490 A1
(43) Pub. Date: Oct. 2, 2008

(54) SEMICONDUCTOR DEVICE AND METHOD FOR DRIVING THE SAME

(75) Inventor: Jae-Boum PARK, Kyoungki-do (KR)

Correspondence Address: RABIN & Berdo, PC, 1101 14TH STREET, NW, SUITE 500, WASHINGTON, DC, 20005, US

(73) Assignee: Hynix Semiconductor Inc., Kyoungki-Do (KR)

(21) Appl. No.: 11/967,547

(22) Filed: Dec. 31, 2007

(30) Foreign Application Priority Data
Mar. 29, 2007 (KR) 10-2007-0030708

(51) Int. Cl. H03D 13/00

(52) U.S. Cl. 327/42

(57) ABSTRACT

A semiconductor device includes a control unit for outputting an oscillation enable signal in synchronization with transitions of an input clock and buffering the input clock to output a comparison clock corresponding to an activation timing of the oscillation enable signal. A reference frequency generating unit outputs a reference clock having a predetermined frequency based on the oscillation enable signal. First and second counting units count clocking numbers of the reference clock and the comparison clock respectively until a preset count value. A comparing unit compares the clocking number of the reference clock with that of the comparison clock to generate a comparison signal.

### CROSS-REFERENCE TO RELATED APPLICATIONS

The present invention claims priority of Korean patent application number 10-2007-0030708, filed on Mar. 29, 2007, which is incorporated by reference in its entirety.

### BACKGROUND OF THE INVENTION

The present invention relates to a semiconductor device and a method for driving the semiconductor device, and more particularly, to a semiconductor device and a method for detecting a frequency.

A system can be implemented with a plurality of semiconductor devices having various functions. Such a system can include, for example, a semiconductor memory device used to store data. Such a semiconductor memory device can output data corresponding to addresses received from a data processor, e.g., a central processing unit (CPU), or store the data received from the data processor into unit cells corresponding to addresses input together with the data.

As the operating speed of the system is increased, the data processor requires the semiconductor memory device to input/output data at a higher speed. As semiconductor integrated circuit (IC) technologies develop rapidly, the operating speed of the data processor increases. The data input/output speed of the semiconductor memory device does not keep up with the increased operating speed of the data processor.

Many attempts have been made to develop semiconductor memory devices that can increase data input/output speed up to the level required by the data processor. One of these semiconductor memory devices is a synchronous memory device that outputs data at each period of a system clock. Specifically, the synchronous memory device outputs or receives data to or from the data processor in synchronization with the system clock. However, because even the synchronous memory device could not keep up with the operating speed of the data processor, a double data rate (DDR) synchronous memory device was developed. The DDR synchronous memory device outputs or receives data at each transition of the system clock. That is, the DDR synchronous memory device outputs or receives data in synchronization with both falling edges and rising edges of the system clock.

Such a memory device includes various internal circuits for processing the inputted system clock because the DDR synchronous memory device outputs the data by using a system clock inputted externally. For example, a data output circuit outputs the data in synchronization with the transitions of the system clock.

In general, the frequency of the inputted system clock varies according to the system that the memory device is applied to. Recently, the memory device has been required to cover a broader band of frequency of the system clock. However, it is difficult for the various internal circuits to reliably operate at both a high frequency and a low frequency. Accordingly, two circuit blocks are provided in parallel, so that one of the circuit blocks is used to access the data when the system clock has the high frequency and the other circuit block is used to access the data when the system clock has the low frequency. To achieve this, a circuit for more accurately detecting the frequency of the system clock is required.

### SUMMARY OF THE INVENTION

Embodiments of the present invention are directed to providing a semiconductor device capable of accurately detecting a frequency of an input clock.

Embodiments of the present invention are also directed to providing a semiconductor device capable of selecting a load driving ability by detecting a frequency of an input clock.

Further embodiments of the present invention are directed to providing a semiconductor device capable of controlling a voltage level of an internal voltage according to a frequency of an input clock.

In accordance with a first aspect of the present invention, there is provided a semiconductor device, including: a control unit configured to output an oscillation enable signal synchronized with transitions of an input clock and to buffer the input clock to output a comparison clock corresponding to an activation timing of the oscillation enable signal; a reference frequency generating unit configured to output a reference clock having a predetermined frequency based on the oscillation enable signal; first and second counting units configured to count clocking numbers of the reference clock and the comparison clock respectively until a preset count value; and a comparing unit configured to compare the clocking number of the reference clock with that of the comparison clock to generate a comparison signal.

In accordance with a second aspect of the present invention, there is provided a method for driving a semiconductor device, including: outputting an oscillation enable signal synchronized with transitions of an input clock and outputting a comparison clock corresponding to an activation timing of the oscillation enable signal by buffering the input clock; outputting a reference clock having a predetermined reference frequency based on the oscillation enable signal; counting clocking numbers of the reference clock and the comparison clock respectively until a preset count value; and generating a comparison signal by comparing the clocking number of the reference clock with that of the comparison clock.

In accordance with a third aspect of the present invention, there is provided a semiconductor device, including: a control unit configured to output an oscillation enable signal synchronized with transitions of an input clock and to buffer the input clock to output a comparison clock corresponding to an activation timing of the oscillation enable signal; a reference frequency generating unit configured to output a reference clock having a predetermined frequency based on the oscillation enable signal; first and second counting units configured to count clocking numbers of the reference clock and the comparison clock respectively until the preset count value; and a comparing unit configured to compare the clocking number of the reference clock with that of the comparison clock to generate a comparison signal; a first circuit unit configured to perform an operation with a first frequency; a second circuit unit configured to perform an operation with a second frequency lower than the first frequency; and a multiplexing unit configured to output an output signal by selecting one of outputs of the first and second circuit units in response to the comparison signal.

In accordance with a fourth aspect of the present invention, there is provided a method for driving a semiconductor device, including: outputting an oscillation enable signal synchronized with transitions of an input clock and outputting a comparison clock corresponding to an activation timing of the oscillation enable signal by buffering the input clock; outputting a reference clock having a predetermined reference frequency based on the oscillation enable signal; counting clocking numbers of the reference clock and the comparison clock until a preset count value; generating a comparison signal by comparing the clocking number of the reference clock with that of the comparison clock; outputting a first operating signal by performing an operation with a first frequency; outputting a second operating signal by performing an operation with a second frequency lower than the first frequency; and outputting an output signal by selecting one of the first operating signal and the second operating signal in response to the comparison signal.

In accordance with a fifth aspect of the present invention, there is provided a semiconductor device, including: a control unit configured to output an oscillation enable signal synchronized with transitions of an input clock and to buffer the input clock to output a comparison clock corresponding to an activation timing of the oscillation enable signal; a reference frequency generating unit configured to output a reference clock having a predetermined frequency based on the oscillation enable signal; first and second counting units configured to count clocking numbers of the reference clock and the comparison clock until a preset count value; and a comparing unit configured to compare the clocking number of the reference clock with that of the comparison clock to generate a comparison signal; a first voltage generating unit configured to generate a first operating voltage; and a second voltage generating unit configured to generate a second operating voltage having substantially a same voltage level as that of the first operating voltage in response to the comparison signal.

### BRIEF DESCRIPTION OF THE DRAWINGS

FIG. 1 is a schematic block diagram of a semiconductor device in accordance with a first embodiment of the present invention;

FIG. 2 is a circuit diagram of the semiconductor device shown in FIG. 1;

FIG. 3 is a waveform diagram showing an operation of the semiconductor device according to FIG. 2 when a frequency of an input clock is higher than a reference frequency;

FIG. 4 is a waveform diagram showing an operation of the semiconductor device according to FIG. 2 when a frequency of an input clock is lower than a reference frequency;

FIG. 5 is a schematic block diagram of a semiconductor device in accordance with a second embodiment of the present invention; and

FIG. 6 is a schematic block diagram of a semiconductor device in accordance with a third embodiment of the present invention.

### DESCRIPTION OF SPECIFIC EMBODIMENTS

Hereinafter, a semiconductor memory device capable of detecting a frequency of an input clock in accordance with exemplary embodiments of the present invention will be described in detail with reference to the accompanying drawings.

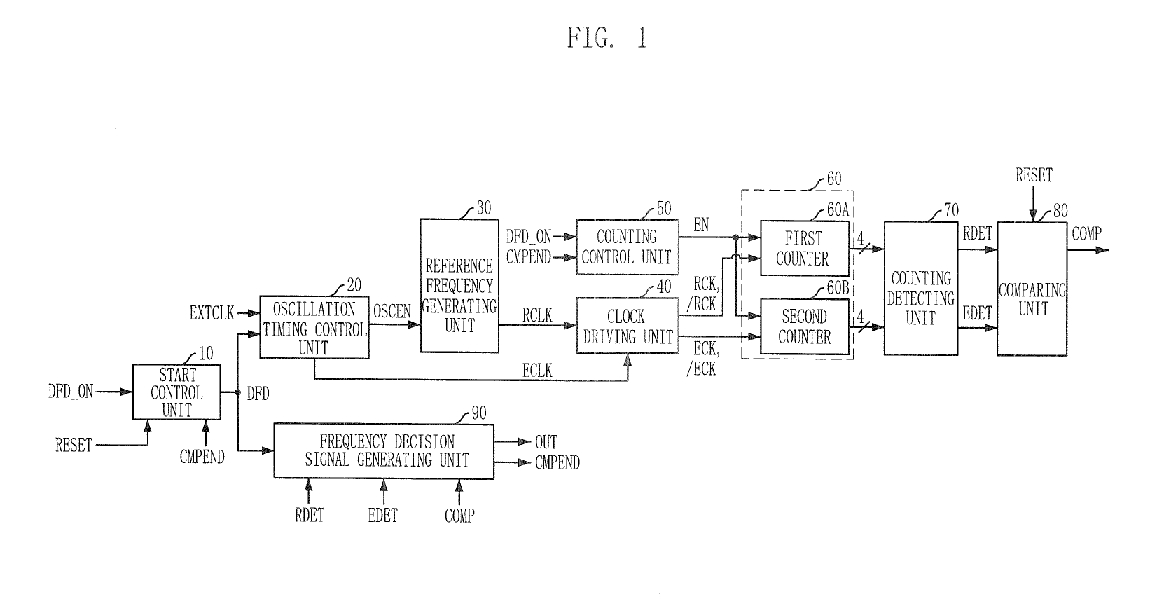

FIG. 1 is a block diagram of a semiconductor device in accordance with a first embodiment of the present invention.

As shown, the semiconductor device in accordance with the first embodiment of the present invention includes a start control unit 10, an oscillation timing control unit 20, a reference frequency generating unit 30, a clock driving unit 40, a counting control unit 50, a counting unit 60, a counting detecting unit 70, a comparing unit 80, and a frequency decision signal generating unit 90.

The start control unit 10 generates a reference signal DFD based on a frequency detecting start signal DFD_ON. The start control unit 10 is reset in response to a reset signal RESET and stops it's operating according to a completion signal CMPEND.

The oscillation timing control unit 20 outputs an oscillation enable signal OSCEN and a first comparison clock ECLK. The oscillation enable signal OSCEN is activated in response to a transition of an input clock EXTCLK and the first comparison clock ECLK is generated by buffering the input clock EXTCLK. In this time, an activation timing of the oscillation enable signal OSCEN is synchronized with a transition timing of the first comparison clock ECLK. As a result, it is possible to synchronize the transition timing of the first comparison clock ECLK with that of a first reference clock RCLK outputted from the reference frequency generating unit 30.

The reference frequency generating unit 30 outputs the first reference clock RCLK based on the oscillation enable signal OSCEN. The first reference clock RCLK is activated in response to the oscillation enable signal OSCEN and has a predetermined reference frequency.

The clock driving unit 40 outputs a second reference clock pair RCK and /RCK, and a second comparison clock pair ECK and /ECK based on the first reference clock RCLK and the first comparison clock ECLK. Each of the second reference clock pair RCK and /RCK and the second comparison clock pair ECK and /ECK has a driving ability higher than that of the first reference clock RCLK and the first comparison clock ECLK.

The counting control unit 50 outputs a counting enable signal EN to be activated in response to the frequency detecting start signal DFD_ON and inactivated in response to the completion signal CMPEND.

The counting unit 60 includes a first counter 60A and a second counter 60B. The first counter 60A counts the clocking number of the second reference clock pair RCK and /RCK in response to the counting enable signal EN, and the second counter 60B counts the clocking number of the second comparison clock pair ECK and /ECK in response to the counting enable signal EN. In the following illustrative example, it is assumed that the first and second counters 60A and 60B are 4-bit counters. In this example, the first counter 60A is activated in response to the counting enable signal EN and outputs a 4-bit signal of “1111” after counting the 16th clocking number of the second reference clock pair RCK and /RCK. Further, the second counter 60B is activated in response to the counting enable signal EN and outputs a 4-bit signal of “1111” after counting the 16th clocking number of the second comparison clock pair ECK and /ECK.

The counting detecting unit 70 outputs a first detecting signal RDET in response to the 4-bit signal of “1111” outputted from the first counter 60A, and a second detecting signal EDET in response to the 4-bit signal of “1111” outputted from the second counter 60B.

The comparing unit 80 generates a comparison signal COMP by comparing an activation timing of the first detecting signal RDET with that of the second detecting signal EDET.

The frequency decision signal generating unit 90 generates a frequency decision signal OUT and the completion signal CMPEND based on the comparison signal COMP and the first and second detecting signals RDET and EDET. The frequency decision signal OUT determines which frequency is the higher of the reference frequency of the first reference clock RCLK and the frequency of the input clock EXTCLK. The completion signal CMPEND stops the frequency detecting operation of the semiconductor device.

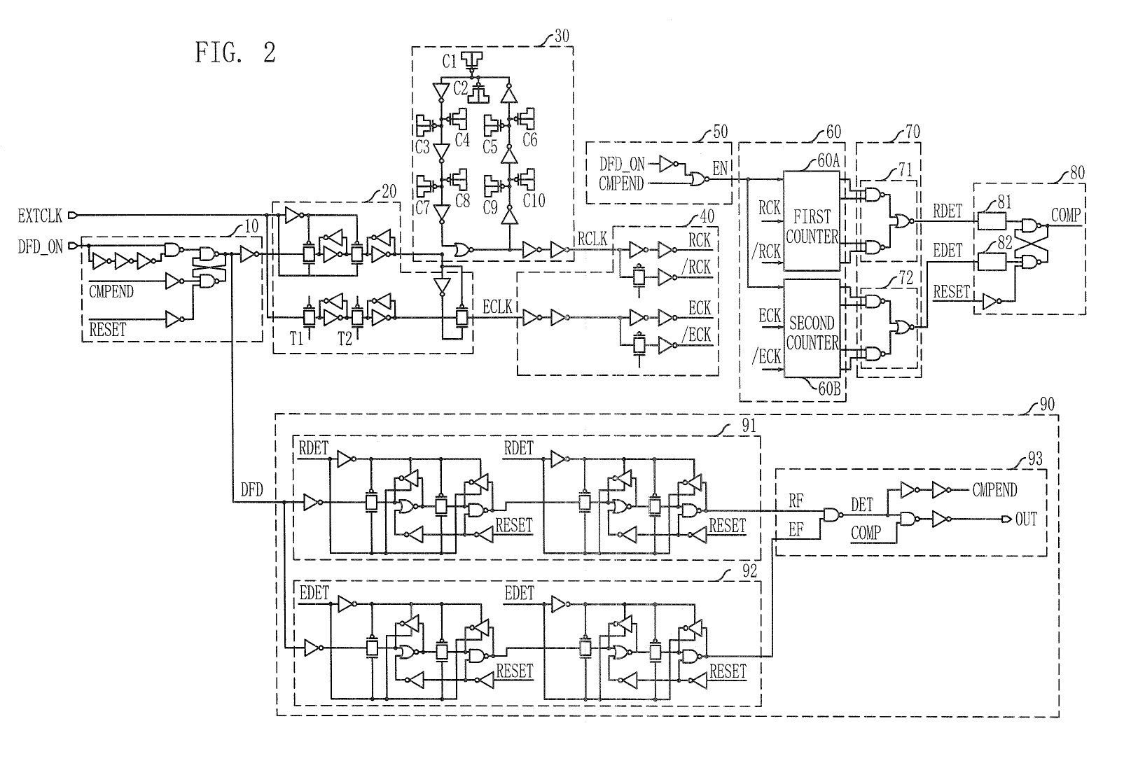

FIG. 2 is a circuit diagram of the semiconductor device shown in FIG. 1.

As shown, the start control unit 10 receives and latches the frequency detecting start signal DFD_ON to output the latched signal as the reference signal DFD. The start control unit 10 inactivates the reference signal DFD in response to the reset signal RESET and the completion signal CMPEND.

The oscillation timing control unit 20 outputs the oscillation enable signal OSCEN in synchronization with the transition of the input clock EXTCLK and outputs the first comparison clock ECLK by buffering the input clock EXTCLK. For this, the oscillation timing control unit 20 includes first and second transmission gates T1 and T2 always enabled for synchronizing the activation timing of the oscillation enable signal OSCEN with an output timing of the first comparison clock ECLK. Accordingly, the activation timing of the oscillation enable signal OSCEN is substantially the same as the transition timing of the first comparison clock ECLK.

The reference frequency generating unit 30 is implemented with a ring oscillator including first to tenth capacitors C1 to C10, six inverters and a NAND gate for receiving the oscillation enable signal OSCEN. The reference frequency of the first reference clock RCLK outputted from the reference frequency generating unit 30 can be adjusted by selectively connecting the first to tenth capacitors C1 to C10.

In the first embodiment, the first and second counters 60A and 60B are implemented with the 4-bit counter for comparing a frequency of the second reference clock pair RCK and /RCK with that of the second comparison clock pair ECK and /ECK. It is possible to use various counters for counting a plurality of bits.

The counting detecting unit 70 includes a first detecting signal generator 71 and a second detecting signal generator 72. The first detecting signal generator 71 generates the first detecting signal RDET when the 4-bit signal outputted from the first counter 60A reaches a predetermined value. The second detecting signal generator 72 generates the second detecting signal EDET when the 4-bit signal outputted from the second counter 60B reaches a preset value.

The comparing unit 80 includes first and second pulse generators 81 and 82, each for generating a corresponding pulse for easily comparing the activation timing of the first detecting signal RDET with that of the second detecting signal EDET. The comparing unit 80 further includes a latch for receiving output signals of the first and second pulse generators 81 and 82 to output the comparison signal COMP.

The frequency decision signal generating unit 90 receives the comparison signal COMP and outputs it as the frequency decision signal OUT in response to the latest activation timing of the first and second detecting signals RDET and EDET.

In detail, the frequency decision signal generating unit 90 includes first and second frequency detectors 91 and 92, and a frequency decision signal output unit 93. The first frequency detector 91 receives the reference signal DFD in response to the first detecting signal RDET to output a first frequency detecting signal RF. The second frequency detector 92 receives the reference signal DFD in response to the second detecting signal EDET to output a second frequency detecting signal EF. The frequency decision signal output unit 93 receives the first and second frequency detecting signals RF and EF to output a result signal DET, and outputs the frequency decision signal OUT in response to the comparison signal COMP and the result signal DET. Further, the decision signal output unit 93 outputs the completion signal CMPEND based on the result signal DET. The completion signal CMPEND is used to stop operations of the start control unit 10 and the counting control unit 50.

As described above, the frequency decision signal OUT is finally generated and thus the start control unit 10 and the counting control unit 50 stop their operations. Accordingly, it is possible to prevent additional current consumption. In the present invention, if the frequency decision signal OUT has a logic low level, the reference frequency of the first reference clock RCLK is higher than the frequency of the input clock EXTCLK. Otherwise, the frequency of the input clock EXTCLK is higher than the reference frequency of the first reference clock RCLK.

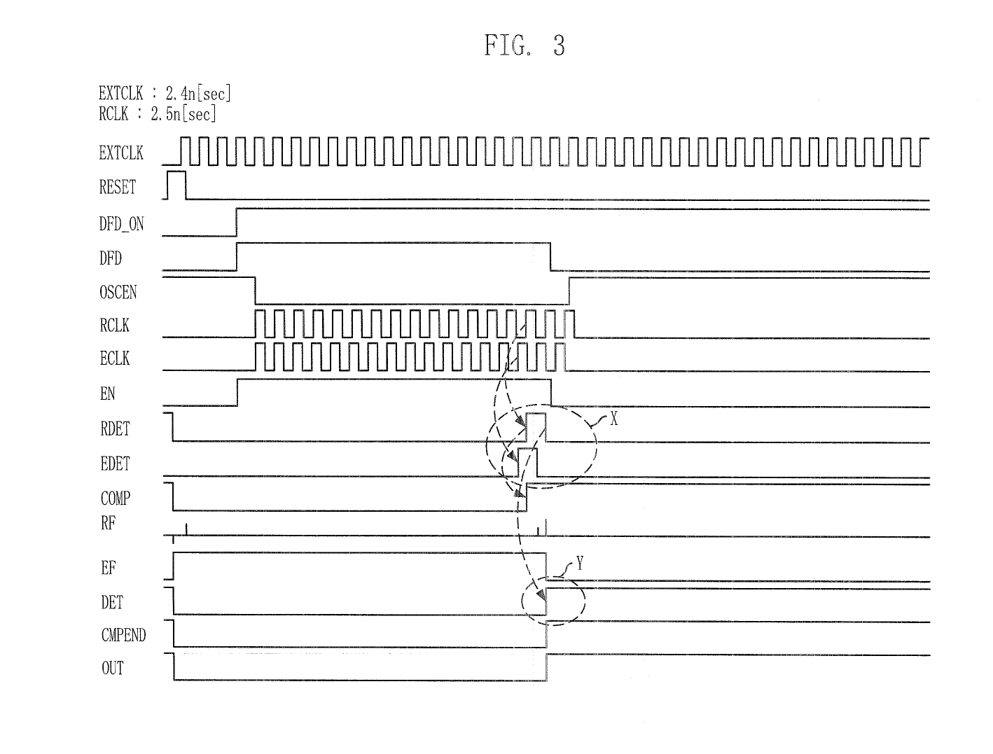

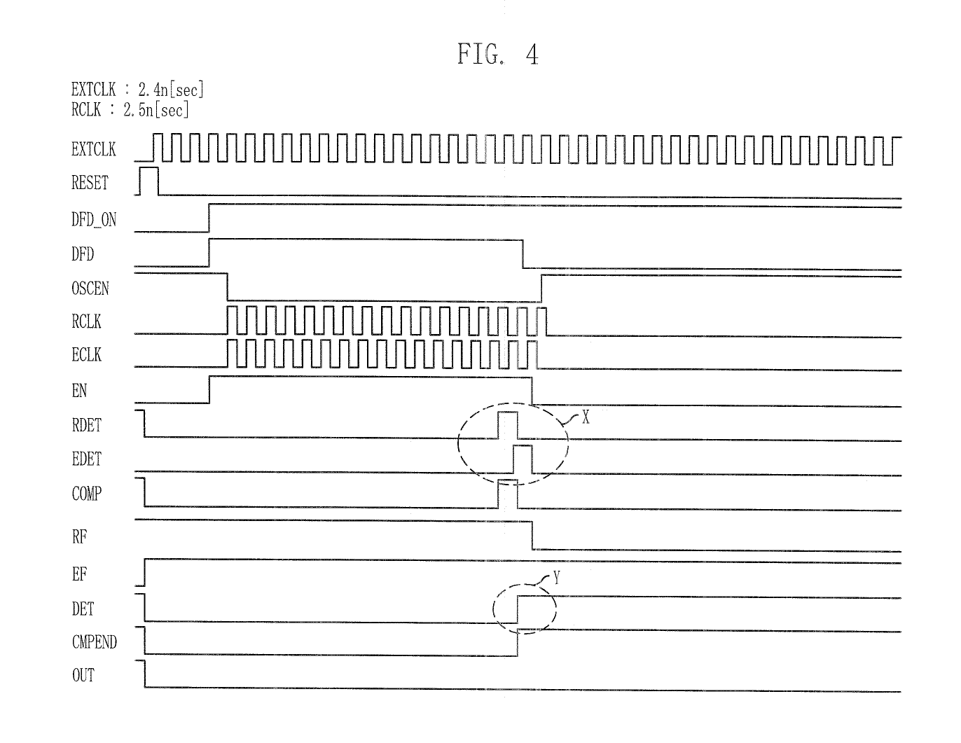

FIGS. 3 and 4 are waveform diagrams showing operation of the semiconductor device according to FIG. 2.

In FIG. 3, it is assumed that a period of the input clock EXTCLK is 2.4 ns and a period of the first reference clock RCLK is 2.5 ns. That is, the frequency of the input clock EXTCLK is higher than the reference frequency of the first reference clock RCLK. Accordingly, the first detecting signal RDET is activated after the second detecting signal EDET is activated (see “X”), and the result signal DET becomes a logic high level in response to the latest activation timing of the first and second detecting signals RDET and EDET, i.e., the timing of the first detecting signal RDET (see “Y”). Further, the completion signal CMPEND and the frequency decision signal OUT become a logic high level in response to the result signal DET.

In FIG. 4, it is assumed that a period of the input clock EXTCLK is 2.6 ns and a period of the first reference clock RCLK is 2.5 ns. That is, the frequency of the input clock EXTCLK is lower than the reference frequency of the first reference clock RCLK. Accordingly, the first detecting signal RDET is activated before the second detecting signal EDET is activated (see “X”), and the result signal DET becomes a logic high level in response to the latest activation timing of the first and second detecting signals RDET and EDET, i.e., the timing of the second detecting signal EDET (see “Y”). Furthermore, the completion signal CMPEND becomes a logic high level and the frequency decision signal OUT becomes a logic low level in response to the result signal DET.

FIG. 5 is a block diagram of a semiconductor device in accordance with a second embodiment of the present invention.

As shown, the semiconductor device in accordance with the second embodiment of the present invention includes a frequency detecting unit 100, a high frequency circuit 200, a low frequency circuit 300, and a multiplexer 400.

The frequency detecting unit 100 may be implemented by a circuit similar to that shown in FIGS. 1 and 2. The frequency detecting unit 100 outputs a frequency decision signal OUT based on an input clock EXTCLK, a reset signal RESET, and a frequency detecting start signal DFD_ON. The high frequency circuit 200 performs an operation with a first frequency. The low frequency circuit 300 performs an operation with a second frequency lower than the first frequency. The multiplexer 400 outputs an output signal OUTPUT by selecting one of outputs of the high frequency circuit 200 and the low frequency circuit 300 in response to the frequency decision signal OUT.

Accordingly, the semiconductor device of the present invention can operate in response to the frequency of the input clock with a proper timing. Further, while the multiplexer 400 selects one of the outputs of the high frequency circuit 200 and the low frequency circuit 300 in the second embodiment, the high frequency circuit 200 and the low frequency circuit 300 may selectively operate in response to the frequency decision signal OUT, thereby reducing power consumption.

In case of a semiconductor memory device, an operating margin can be different according to a frequency of a system clock. In accordance with the second embodiment of the present invention, the semiconductor memory device may include a data processing circuit that detects the frequency of the system clock to thereby cope with both a high frequency and a low frequency. Accordingly, the semiconductor memory device can efficiently process data by operating the data processing circuit with the frequency of the system clock.

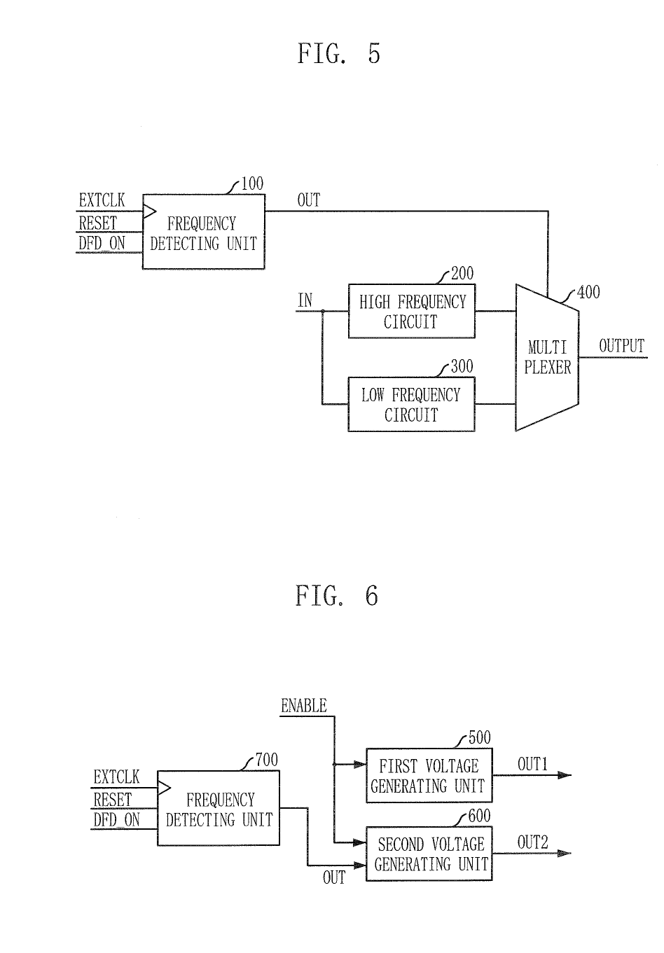

FIG. 6 is a block diagram of a semiconductor device in accordance with a third embodiment of the present invention.

As shown, the semiconductor device in accordance with the third embodiment of the present invention includes a frequency detecting unit 700, a first voltage generating unit 500, and a second voltage generating unit 600.

The frequency detecting unit 700 may be implemented by a circuit similar to that shown in FIGS. 1 and 2. The frequency detecting unit 700 outputs a frequency decision signal OUT based on an input clock EXTCLK, a reset signal RESET, and a frequency detecting start signal DFD_ON. The first voltage generating unit 500 generates a first operating voltage OUT1 in response to an enable signal ENABLE. The second voltage generating unit 600 generates a second operating voltage OUT2 having substantially the same voltage level as that of the first operating voltage OUT1 in response to the enable signal ENABLE. Further, the second voltage generating unit 600 selectively outputs the second operating voltage OUT2 in response to the frequency decision signal OUT.

In general, a semiconductor memory device has a different load driving ability for internally driving an operating voltage according to a frequency of an operating clock. When the frequency of the operating clock is low, the load driving ability of the operating voltage may have a relatively low value. When the frequency of the operating clock is high, the load driving ability of the operating voltage may have a relatively high value.

In accordance with the third embodiment of the present invention, the semiconductor memory device includes the second voltage generating unit 600 for generating an auxiliary voltage, i.e., the second operating voltage OUT2, as well as the first voltage generating unit 500. The second voltage generating unit 600 operates in response to the frequency decision signal OUT so that the load driving ability of the operating voltage can be optimized according to the frequency of the operating clock. Accordingly, the semiconductor memory device can reduce power consumption by optimizing the load driving ability of the operating voltage according to the frequency of the operating clock.

As described above, the semiconductor devices in accordance with the embodiments of the present invention can easily detect a frequency of an input clock. The semiconductor device can supply an operating voltage having an appropriate load driving ability according to whether the frequency of the input clock is a high frequency or a low frequency, thereby efficiently reducing power consumption. Furthermore, the semiconductor device can efficiently control data processing time according to whether the frequency of the input clock is a high frequency or a low frequency.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a control unit configured to output an oscillation enable signal synchronized with transitions of an input clock, and to buffer the input clock to output a comparison clock corresponding to an activation timing of the oscillation enable signal;
a reference frequency generating unit configured to output a reference clock having a predetermined frequency based on the oscillation enable signal;
first and second counting units configured to count clocking numbers of the reference clock and the comparison clock respectively until a preset count value; and
a comparing unit configured to compare the clocking number of the reference clock with that of the comparison clock to generate a comparison signal.

2. The semiconductor device of claim 1, wherein the control unit includes:
a start control unit configured to generate a reference signal based on a frequency detecting start signal; and
an oscillation timing control unit configured to output the oscillation enable signal in response to the input clock and the reference signal, and to output the comparison clock by latching the input clock in response to the activation timing of the oscillation enable signal.

3. The semiconductor device of claim 1, wherein the reference frequency generating unit includes a ring oscillator.

4. The semiconductor device of claim 1, further comprising a clock driver configured to increase a load driving ability of the reference clock to provide the reference clock to the first counting unit.

5. The semiconductor device of claim 1, further comprising a clock driver configured to increase a load driving ability of the comparison clock to provide the comparison clock to the second counting unit.

6. The semiconductor device of claim 1, wherein the comparing unit includes:
a first detecting signal generator configured to generate a first detecting signal when the clocking number of the reference clock reaches the preset count value;
a second detecting signal generator configured to generate a second detecting signal when the clocking number of the comparison clock reaches the preset value; and
a comparison signal generator configured to generate the comparison signal by comparing an activation timing of the first detecting signal with that of the second detecting signal.

7. The semiconductor device if claim 6, further comprising a frequency decision signal generating unit configured to output the comparison signal as a frequency decision signal in response to a latest activation timing of the first and second detecting signals.

8. A method for driving a semiconductor device, comprising:
outputting an oscillation enable signal synchronized with transitions of an input clock, and outputting a comparison clock corresponding to an activation timing of the oscillation enable signal by buffering the input clock;
outputting a reference clock having a predetermined reference frequency based on the oscillation enable signal;
counting clocking numbers of the reference clock and the comparison clock respectively until the preset count value; and
generating a comparison signal by comparing the clocking number of the reference clock with that of the comparison clock.

9. The method of claim 8, wherein outputting the comparison clock includes:
generating a reference signal based on a frequency detecting start signal;
outputting the oscillation enable signal in response to the input clock and the reference signal; and
outputting the comparison clock by latching the input clock in response to the activation timing of the oscillation enable signal.

10. The method of claim 8, wherein counting the clocking number of the reference clock includes increasing a lead driving ability of the reference clock.

11. The method of claim 8, wherein counting other clocking number of the comparison clock includes increasing a load driving ability of the comparison clock.

12. The method of claim 8, wherein generating the comparison signal includes:
activating a first detecting signal when the clocking number of the reference clock reaches the preset count value;
activating a second detecting signal when the clocking number of the comparison clock reaches the preset value; and
generating the comparison signal by comparing an activation timing of the first detecting signal with that of the second detecting signal.

13. A semiconductor device, comprising:
a control unit configured to output an oscillation enable signal synchronized with transitions of an input clock, and to buffer the input clock to output a comparison clock corresponding to an activation timing of the oscillation enable signal;
a reference frequency generating unit configured to output a reference clock having a predetermined frequency based on the oscillation enable signal;
first and second counting units configured to count clocking numbers of the reference clock and the comparison clock respectively until a preset count value; and
a comparing unit configured to compare the clocking number of the reference clock with that of the comparison clock to generate a comparison signal;
a first circuit unit configured to perform an operation with a first frequency;
a second circuit unit configured to perform an operation with a second frequency lower than the first frequency; and
a multiplexing unit configured to output an output signal by selecting one of outputs of the first and second circuit units in response to the comparison signal.

14. The semiconductor device of claim 13, wherein the control unit includes:
a start control unit configured to generate a reference signal based on a frequency detecting start signal; and
an oscillation timing control unit configured to output the oscillation enable signal in response to the input clock and the reference signal, and to output the comparison clock by latching the input clock in response to the activation timing of the oscillation enable signal.

15. The semiconductor device of claim 14, wherein the comparing unit includes:
a first detecting signal generator configured to generate a first detecting signal when the clocking number of the reference clock reaches the preset count value;
a second detecting signal generator configured to generate a second detecting signal when the clocking number of the comparison clock reaches the preset value; and
a comparison signal generator configured to generate the comparison signal by comparing an activation timing of the first detecting signal with that of the second detecting signal.

16. The semiconductor device of claim 15, further comprising a frequency decision signal generating unit configured to output the comparison signal as a frequency decision signal in response to a latest activation timing of the first and second detecting signals.

17. A method for driving a semiconductor device, comprising:
outputting an oscillation enable signal synchronized with transitions of an input clock, and outputting a comparison clock corresponding to an activation timing of the oscillation enable signal by buffering the input clock;
outputting a reference clock having a predetermined reference frequency based on the oscillation enable signal;
counting clocking numbers of the reference clock and the comparison clock until a preset count value;
generating a comparison signal by comparing the clocking number of the reference clock with that of the comparison clock;
outputting a first operating signal by performing an operation with a first frequency;
outputting a second operating signal by performing an operation with a second frequency lower than the first frequency; and
outputting an output signal by selecting one of the first operating signal and the second operating signal in response to the comparison signal.

18. The method of claim 17, wherein outputting the oscillation enable signal and the comparison clock includes:
generating a reference signal based on a frequency detecting start signal;
outputting the oscillation enable signal in response to the input clock and the reference signal; and
outputting the comparison clock by latching the input clock in response to the activation timing of the oscillation enable signal.

19. The method of claim 17, wherein generating the comparison signal includes:
activating a first detecting signal when the clocking number of the reference clock reaches the preset count value;
activating a second detecting signal when the clocking number of the comparison clock reaches the preset value; and
generating the comparison signal by comparing an activation timing of the first detecting signal with that of the second detecting signal.

20. The method of claim 19, further comprising outputting the comparison signal as a frequency decision signal in response to a latest activation timing of the first and second detecting signals.

21. The method of claim 20, wherein outputting the frequency decision signal includes:
outputting a first frequency detecting signal by receiving the reference signal in response to the first detecting signal;
outputting a second frequency detecting signal by receiving the reference signal in response to the second detecting signal; and
outputting the frequency decision signal by receiving the comparison signal in response to the first and second frequency detecting signals.

22. The method of claim 21, wherein outputting the frequency decision signal further includes:
outputting a completion signal in response to the activation timing of the first and second detecting signals; and
disabling outputting of the oscillation enable signal and the comparison clock in response to the completion signal.

23. A semiconductor device, comprising:
a control unit configured to output an oscillation enable signal synchronized with transitions of an input clock, and to buffer the input clock to output a comparison clock corresponding to an activation timing of the oscillation enable signal;
a reference frequency generating unit configured to output a reference clock having a predetermined frequency based on the oscillation enable signal;
first and second counting units configured to count clocking numbers of the reference clock and the comparison clock respectively until a preset count value; and
a comparing unit configured to compare the clocking number of the reference clock with that of the comparison clock to generate a comparison signal;
a first voltage generating unit configured to generate a first operating voltage; and
a second voltage generating unit configured to generate a second operating voltage having substantially a same voltage level as that of the first operating voltage in response to the comparison signal.

24. The semiconductor device of claim 23, wherein the control unit includes:
a start control unit configured to generate a reference signal based on a frequency detecting start signal; and
an oscillation timing control unit configured to output the oscillation enable signal in response to the input clock and the reference signal, and outputting the comparison clock by latching the input clock in response to the activation timing of the oscillation enable signal.

25. The semiconductor device as recited in claim 23, wherein the comparing unit includes:
a first detecting signal generator configured to generate a first detecting signal when the clocking number of the reference clock reaches the preset count value;
a second detecting signal generator configured to generate a second detecting signal when the clocking number of the comparison clock reaches the preset value; and
a comparison signal generator configured to generate the comparison signal by comparing an activation timing of the first detecting signal with that of the second detecting signal.
